(19) United States
(12) Patent Application Publication
(10) Pub. No.: US 2023/0100353 A1
(43) Pub. Date: Mar. 30, 2023

(54) SEMICONDUCTOR LIGHT-EMITTING ELEMENT AND LIGHT-EMITTING DIODE PACKAGE STRUCTURE INCLUDING THE SAME

(71) Applicant: TIANJIN SANAN OPTOELECTRONICS CO., LTD., Tianjin (CN)

(72) Inventors: Kunte LIN, Tianjin (CN); Jiansheng QIU, Xiamen (CN)

(21) Appl. No.: 18/060,306

(22) Filed: Nov. 30, 2022

Related U.S. Application Data
(63) Continuation-in-part of application No. PCT/CN2020/100151, filed on Jul. 3, 2020.

(51) Int. Cl. H01L 33/38; H01L 33/62; H01L 33/12; H01L 33/30

(52) U.S. Cl. CPC H01L 33/382; H01L 33/62; H01L 33/12; H01L 33/30

(57) ABSTRACT

A light-emitting element includes a semiconductor epitaxial structure, a passivation layer, a first electrode, a second electrode, and a mechanical buffer layer. The semiconductor epitaxial structure includes a first semiconductor layer, an active layer disposed on the first semiconductor layer, and a second semiconductor layer disposed on the active layer opposite to the first semiconductor layer. The passivation layer is disposed on the semiconductor epitaxial structure. The first electrode is disposed on the passivation layer, and extends through the passivation layer to be electrically connected to the first semiconductor layer. The second electrode is disposed on the passivation layer, and extends through the passivation layer to be electrically connected to the second semiconductor layer. The mechanical buffer layer is disposed between the passivation layer and the second semiconductor layer. A light-emitting diode package structure including at least one the light-emitting element is also disclosed.

### CROSS-REFERENCE TO RELATED APPLICATION

This application is a bypass continuation-in-part (CIP) of International Application No. PCT/CN2020/100151, filed on Jul. 3, 2020.

### FIELD

The disclosure relates to an optoelectronic device, and more particularly to a semiconductor light-emitting element.

### BACKGROUND

A light-emitting diode (LED) is a semiconductor diode capable of converting electricity into light. In comparison with a conventional lighting, the LED is considered to be one of the light sources with the most potential for next-generation displays, and is widely used in general lighting, signal lights, backlights, automotive lighting, and display screens with various sizes, etc., due to its advantages such as high brightness, high efficiency, small volume, long lifetime, etc.

A LED chip is a key component in a LED device. The LED chip is classified into different types, such as a face-up LED, a flip-chip LED and a vertical LED according to positions of electrodes in the LED chip. Since the flip-chip LED has advantages of high luminous efficiency, good heat dissipation, improved packaging reliability, and high production yield, a process for forming a flip-chip LED chip becomes important.

The flip-chip LED chip includes a substrate, a main unit disposed on the substrate, and two electrodes electrically connected to the main unit and disposed at the same side of the flip-chip LED chip opposite to the substrate. The main unit includes an epitaxial structure, a reflective layer, a passivation layer, or other suitable structures formed prior to forming the electrodes. During a packaging process of the flip-chip LED chip, the flip-chip LED chip is lifted up by an ejector pin which may abut against a front side of the flipped LED distal from the substrate and in position between the two electrodes. When the ejector pin acts on the front side of the flipped LED, and applies an upward force thereto, the main unit is easily damaged, which may adversely affect the reliability of the flip-chip LED chip. In order to prevent the main unit from being damaged by the ejector pin, an anti-ejector-pin buffer layer, which is made of an insulating material such as silicon dioxide or silicon nitride and which has a thickness greater than 0.5 μm, may be disposed on the front side of the flip-chip LED chip. However, due to a poor ductility of the insulating material for forming the anti-ejector-pin buffer layer, a stress caused by the ejector pin may be accumulated on the front side of the flip-chip LED chip, and may not be effectively released. Thus, the main unit may still be damaged. Although the thickness of the anti-ejector-pin buffer layer may be increased in order to prevent the main unit from being damaged, the brightness of the flip-chip LED chip may be reduced due to increased absorption of light emitted from the main unit which is caused by increased thickness of the anti-ejector-pin buffer layer.

### SUMMARY

Therefore, an object of the disclosure is to provide a light-emitting element that can alleviate at least one of the drawbacks of the prior art.

According to one aspect of the disclosure, the light-emitting element includes a semiconductor epitaxial structure, a passivation layer, a first electrode, a second electrode, and a mechanical buffer layer.

The semiconductor epitaxial structure has a first surface and a second surface opposite to the first surface, and includes a first semiconductor layer defining the second surface, an active layer disposed on the first semiconductor layer opposite to the second surface to expose a portion of the first semiconductor layer, and a second semiconductor layer disposed on the active layer opposite to the first semiconductor layer to expose the exposed portion of the first semiconductor layer. The second semiconductor layer has a conductivity type different from that of the first semiconductor layer, and defines the first surface opposite to the active layer. The passivation layer is disposed on the first surface of the semiconductor epitaxial structure and the exposed portion of the first semiconductor layer. The first electrode is disposed on the passivation layer, and extends through the passivation layer to be electrically connected to the exposed portion of the first semiconductor layer. The second electrode is disposed on the passivation layer, and extends through the passivation layer to be electrically connected to the second semiconductor layer. The mechanical buffer layer is disposed between the passivation layer and the second semiconductor layer.

According to another aspect of the disclosure, a light-emitting diode package structure includes a mounting substrate and at least one the light-emitting element as mentioned above which is disposed on the mounting substrate.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a first embodiment of a light-emitting element according to the disclosure.

FIG. 2 is a schematic cross-sectional view illustrating a second embodiment of the light-emitting element according to the disclosure.

FIG. 3 is a schematic cross-sectional view illustrating a third embodiment of the light-emitting element according to the disclosure.

FIG. 4 is a schematic cross-sectional view illustrating a fourth embodiment of the light-emitting element according to the disclosure.

FIG. 5 is a schematic cross-sectional view illustrating a light-emitting diode package structure according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

### Embodiment 1

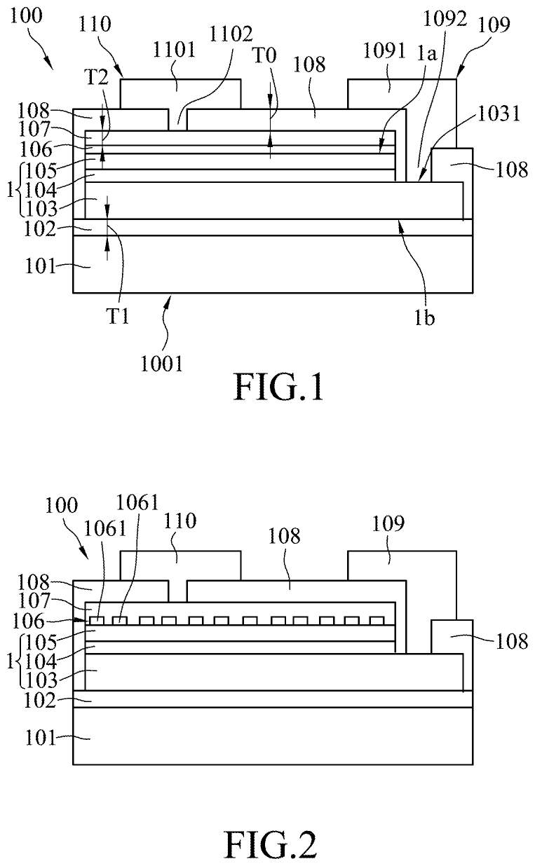

FIG. 1 is a schematic cross-sectional view illustrating a first embodiment of a light-emitting element 100 in accordance with the disclosure. The light-emitting element 100 includes a transparent substrate 101, a transparent bonding layer 102, a semiconductor epitaxial structure 1, a contact structure 106, a mechanical buffer layer 107, a passivation layer 108, a first electrode 109, and a second electrode 110.

The semiconductor epitaxial structure 1 has a first surface 1a and a second surface 1b opposite to the first surface 1a, and includes a first semiconductor layer 103, a second semiconductor layer 105, and an active layer 104 interposed between the first and second semiconductor layers 103, 105. The first semiconductor layer 103 defines the second surface 1b. The active layer 104 is disposed on the first semiconductor layer 103 opposite to the second surface 1b to expose a portion 1031 of the first semiconductor layer 103. The second semiconductor layer 105 is disposed on the active layer 104 opposite to the first semiconductor layer 103 to expose the exposed portion 1031 of the first semiconductor layer 103. The second semiconductor layer 105 defines the first surface 1a opposite to the active layer 104. In some not shown embodiments, the active layer 104 may be disposed on the second semiconductor layer 105 opposite to the first surface 1a to exposed a portion of the second semiconductor layer 105, and the first semiconductor layer 103 is disposed on the active layer 104 opposite to the second semiconductor layer 105 to expose the exposed portion of the second semiconductor layer 105.

The first semiconductor layer 103 has a conductivity type, an electrical property, and/or polarity different from that of the second semiconductor layer 105. Major carriers in one of the first and second semiconductor layers 103, 105 may be electrons or holes according to types of impurities doped in the one of the first and second semiconductor layers 103, 105. For example, when the first semiconductor layer 103 is made of an n-type semiconductor material, a semiconductor material for forming the second semiconductor layer 105 is p-type, and vice versa. The light-emitting element 100 is capable of converting electricity into light through electron-hole recombination which occurs at the active layer 104. The electrons come from one of the first and second semiconductor layers 103, 105, and the holes come from the other one of the first and second semiconductor layers 103, 105. A wavelength of a light emitted from the light-emitting element 100 may be adjusted by controlling physical properties and/or chemical properties of at least one of the first semiconductor layer 103, the active layer 104, and the second semiconductor layer 105 in the semiconductor epitaxial structure 1. In some embodiments, the semiconductor epitaxial structure 1 includes an aluminum gallium indium phosphide-based (AlGaInP-based) material, an aluminum gallium indium nitride-based (AlGaInN-based) material, a zinc oxide-based (ZnO-based) material, or combinations thereof. The active layer 104 may be formed as a single heterostructure (SH), a double heterostructure (DH), a double-side double heterostructure (DDH), or a multi-quantum well (MQW) structure. To be specific, the active layer 104 may be made of an electrically neutral semiconductor material, a p-type semiconductor material, or an n-type semiconductor material. When an applied current passes through the semiconductor epitaxial structure 1 to allow an electron-hole recombination in the active layer 104, an energy generated in the form of light is emitted from the active layer 104. In this embodiment, the active layer 104 includes an AlGaInP-based material, and the light emitted from the active layer 104 may be an amber-based light such as red, orange, or yellow. In some other embodiments, the active layer 104 includes an AlGaInN-based material, and the light emitted from the active layer 104 may be blue or green.

In this embodiment, the exposed portion 1031 of the first semiconductor layer 103 is located at an edge of the first semiconductor layer 103, such that the semiconductor epitaxial structure 1 is formed as a mesa structure, as shown in FIG. 1. In some other embodiments, the semiconductor epitaxial structure 1 has a hole (not shown) extending from the first surface 1a through the second semiconductor layer 105 and the active layer 104 to expose the exposed portion 1031 of the first semiconductor layer 103. In this case, the hole has an inner surface cooperatively defined by the active layer 104 and the second semiconductor layer 105.

The transparent substrate 101 is disposed on the second surface 1b of the semiconductor epitaxial structure 1 through the transparent bonding layer 102 which is interposed between the semiconductor epitaxial structure 1 and the transparent substrate 101. The transparent substrate 101 has a sufficient mechanical strength to support the semiconductor epitaxial structure 1 disposed thereon, and is made of a material which is transparent to permit a light emitted from the active layer 104 to pass through the transparent substrate 101. In some embodiments, the transparent substrate 101 includes a material having a stable chemical property (e.g., good moisture resistance and/or good corrosion resistance). For example, the transparent substrate 101 may include a corrosion-resistant material, such as aluminum (Al), but is not limited thereto. In some embodiments, the transparent substrate 101 has a thermal expansion coefficient similar to that of the semiconductor epitaxial structure 1, a good moisture resistance, and a relatively high thermal conductivity, and may include a material such as gallium phosphide (GaP), silicon carbide (SiC), sapphire, or transparent glass. In order to provide a sufficient mechanical strength to support the semiconductor epitaxial structure 1, the transparent substrate 101 may have a thickness greater than about 50 μm. Furthermore, for ease of machining of the transparent substrate 101 after bonding of the transparent substrate 101 to the semiconductor epitaxial structure 1, the transparent substrate 101 may have a thickness not greater than about 300 μm. In this embodiment, the transparent substrate 101 is made of sapphire.

The transparent bonding layer 102 covers the second surface 1b of the semiconductor epitaxial structure 1. The transparent substrate 101 is bonded to the second surface 1b through the transparent bonding layer 102. The light emitted from the active layer 104 may pass through the transparent bonding layer 102 and the transparent substrate 101 to be extracted from a surface 1001 of the transparent substrate 101 opposite to the semiconductor epitaxial structure 1. The surface 1001 serves as a light-emitting side 1001 of the light-emitting element 100. In some embodiments, the second surface 1b of the semiconductor epitaxial structure 1 is a rough surface to prevent total internal reflection of the light emitted from the active layer 104 reaching the second surface 1b (i.e., an interface between the semiconductor epitaxial structure 1 and the transparent bonding layer 102). The transparent bonding layer 102 may have a refractive index ranging between a refractive index of the first semiconductor layer 103 and a refractive index of the transparent substrate 101. In some embodiments, the refractive index of the transparent substrate 101 is less than that of the transparent bonding layer 102. The refractive index of the transparent bonding layer 102 ranges from about 1.2 to about 3. In this embodiment, the refractive index of the transparent bonding layer 102 ranges from about 1.6 to about 3. In general, silicon dioxide is widely used for forming the transparent bonding layer 102 due to relatively high bonding strength and yield rate. However, silicon dioxide has a relatively low refractive index, which limits the extraction of a light emitted from a semiconductor epitaxial structure and limits the functionality of a sapphire substrate serving as a light-emitting window.

The transparent bonding layer 102 may be formed as a single-layer structure or a multi-layered structure which includes at least one transparent conductive sub-layer. In this embodiment, the transparent bonding layer 102 is formed as a single-layer structure, and includes a transparent conductive material, which may be a metal oxide including zinc (Zn), indium (In), tin (Sn), magnesium (Mg), or combinations thereof. For example, the transparent conductive material for forming the transparent bonding layer 102 may be zinc oxide (ZnO), indium oxide (In₂O₃), tin oxide (SnO₂), indium tin oxide (ITO), indium zinc oxide (IZO), gallium-doped zinc oxide (GZO), or combinations thereof. The transparent conductive material serving as the transparent bonding layer 102 has a refractive index greater than that of silicon dioxide, such that a reflection of the light emitted from the semiconductor epitaxial structure 1 at the interface between the semiconductor epitaxial structure 1 and the transparent bonding layer 102 may be reduced, thereby improving brightness of the light-emitting element 100. Furthermore, since the transparent conductive material serving as the transparent bonding layer 102 is in contact with the first semiconductor layer 103, the transparent bonding layer 102 may have a function of current spreading, so that uniformity of current distribution in the semiconductor epitaxial structure 1 can be improved.

The first electrode 109 and the second electrode 110 are disposed to be electrically connected directly or indirectly to the first semiconductor layer 103 and the second semiconductor layer 105, respectively, so that an external current may be applied to the semiconductor epitaxial structure 1. In some embodiments, when the first semiconductor layer 103 and the second semiconductor layers 105 are respectively made of an n-type semiconductor material and a p-type semiconductor material, the first electrode 109 may be referred to as an n-side electrode, and the second electrode 110 may be referred to as a p-side electrode. In some other embodiments, when the first semiconductor layer 103 and the second semiconductor layer 105 are respectively made of a p-type semiconductor material and an n-type semiconductor material, the first electrode 109 may be referred to as a p-side electrode, and the second electrode 110 may be referred to as an n-side electrode.

In this embodiment, each of the first and second electrodes 109, 110 is formed as a pad electrode which is beneficial for electrical connection with an external circuit, and is disposed at the same side of the semiconductor epitaxial structure 1 opposite to the second surface 1b. The first electrode 109 includes a first pad portion 1091 and a first connecting portion 1092, which are distal from and proximate to the transparent substrate 101, respectively. The first connecting portion 1092 extends from the first pad portion 1091 toward the first semiconductor layer 103 to be electrically connected to the exposed portion 1031 of the first semiconductor layer 103. The second electrode 110 includes a second pad portion 1101 and a second connecting portion 1102, which are distal from and proximate to the transparent substrate 101, respectively. The second connecting portion 1102 extends from the second pad portion 1101 toward the second semiconductor layer 105 to be electrically connected to the second semiconductor layer 105. As viewed from a top of the light-emitting element 100, each of the first and second pad portions 1091, 1101 has a size (i.e., width and/or length) greater than that of each of the first and second connecting portions 1092, 1102. In addition, the first and second pad portions 1091, 1101 are spaced apart from each other to be located at two sides of the light-emitting element 100. The shape and/or size of each of the first and second pad portions 1091, 1101 may vary according to the size of the light-emitting element 100 and/or the configurations/positions of the first and second electrodes 109, 110. For example, the shape of each of the first and second pad portions 1091, 1101 may be a circle or a regular polygon. In some embodiments, each of the first and second pad portions 1091, 1101 may have a circular shape or a circle-like shape in consideration of ease of connection with an external circuit. In some embodiments, each of the first and second pad portions 1091, 1101 may independently have a circular shape with a diameter ranging from about 30 μm to about 150 μm. The shape and/or size of the first pad portion 1091 may be the same as or different from that of the second pad portion 1101.

The passivation layer 108 is disposed to cover the semiconductor epitaxial structure 1, and is provided to protect the semiconductor epitaxial structure 1 and to avoid a short circuit caused by a contact between a solder paste used in packaging and the semiconductor epitaxial structure 1. In this embodiment, the passivation layer 108 is disposed on the first surface 1a of the semiconductor epitaxial structure 1, and extends to cover a side surface of the second semiconductor layer 105, a side surface of the active layer 104, and the exposed portion 1031 of the first semiconductor layer 103. In addition, the passivation layer 108 may further extend to cover a side surface of the first semiconductor layer 103 to be in contact with an edge of the transparent bonding layer 102. The first pad portion 1091 of the first electrode 109 is disposed on the passivation layer 108, and the first connecting portion 1092 extends from the first pad portion 1091 through the passivation layer 108 to be electrically connected to the exposed portion 1031 of the first semiconductor layer 103. The second pad portion 1101 of the second electrode 110 is disposed on the passivation layer 108, and the second connecting portion 1102 extends from the second pad portion 1101 through the passivation layer 108 to be electrically connected to the second semiconductor layer 105. A portion of the passivation layer 108 is disposed between the first pad portion 1091 and the semiconductor epitaxial structure 1, and another portion of the passivation layer 108 is disposed between the second pad portion 1101 and the semiconductor epitaxial structure 1. The passivation layer 108 in position above the mechanical buffer layer 107 has a thickness (TO) ranging from about 0.1 μm to about 1.4 μm. In some embodiments, the passivation layer 108 may be formed as a distributed Bragg reflector (DBR) so as to permit the light emitted from the semiconductor epitaxial structure 1 to be reflected, thereby being extracted from the light-emitting side 1001 of the light-emitting element 100.

The mechanical buffer layer 107 is disposed between the passivation layer 108 and the second semiconductor layer 105 to prevent the semiconductor epitaxial structure 1 from being damaged by an ejector pin used in packing. The mechanical buffer layer 107 may be electrically conductive. The mechanical buffer layer 107 may be transparent or opaque. In this embodiment, the mechanical buffer layer 107 is a transparent conductive layer, and is made of a metal oxide including Zn, In, Sn, Mg, or combinations thereof. For example, the mechanical buffer layer 107 may be made of ZnO, In₂O₃, SnO₂, ITO, IZO, GZO, or combinations thereof. The transparent conductive layer serving as the mechanical buffer layer 107 may further have a function of current spreading, so as to improve uniformity of current distribution in the semiconductor epitaxial structure 1. In addition, the light emitted from the semiconductor epitaxial structure 1 may pass through the transparent conductive layer serving as the mechanical buffer layer 107 without being absorbed due to a transparent property of the transparent conductive layer, thereby improving brightness of the light-emitting element 100. In some embodiments, the mechanical buffer layer 107 may have a thickness (T2) ranging from about 0.1 μm to about 1 μm. When the mechanical buffer layer 107 is too thin (for example, the thickness T2 is less than 0.1 μm), the mechanical buffer layer 107 may have insufficient mechanical strength to prevent the semiconductor epitaxial structure 1 from being damaged by an ejector pin. When the mechanical buffer layer 107 is too thick (for example, the thickness T2 is greater than 1 μm), a light emitted from the semiconductor epitaxial structure 1 may be absorbed by the mechanical buffer layer 107 to an undesirable extent, and production cost for forming the mechanical buffer layer 107 may be relatively high due to a relatively long process time for forming the mechanical buffer layer 107 using, for example, but not limited to, physical vapor deposition (PVD), or chemical vapor deposition (CVD). In some embodiments, the thickness (T2) of the mechanical buffer layer 107 may range from about 0.5 μm to about 1 μm, such that the mechanical buffer layer 107 may effectively prevent the semiconductor epitaxial structure 1 from being damaged by an ejector pin, thereby improving production yield of the light-emitting element 100. It should be noted that with the provision of the mechanical buffer layer 107, the thickness of the passivation layer 108 may be reduced, thereby reducing absorption of light by the passivation layer 108. It is noted that an interface between the mechanical buffer layer 107 and the second semiconductor layer 105 may be an ohmic contact or a schottky contact according to material selection of the mechanical buffer layer 107 and the second semiconductor layer 105. For example, but not limited to, in the case that the second semiconductor layer 105 includes an n-type AlGaInP-based material and the mechanical buffer layer 107 includes ITO, an ohmic contact may not be formed at the interface between the second semiconductor layer 105 and the mechanical buffer layer 107. Therefore, the contact structure 106 is provided for formation of an ohmic contact with the semiconductor layer 105.

The contact structure 106 is disposed between the mechanical buffer layer 107 and the second semiconductor layer 105. The contact structure 106 may be in ohmic contact with the second semiconductor layer 105 and the mechanical buffer layer 107. The contact structure 106 may include Au—Be alloy (AuBe), Au—Ge alloy (AuGe), Au—Ge—Ni alloy (AuGeNi), ITO, silver (Ag), Zn, germanium (Ge), or combinations thereof. In the case that the second semiconductor layer 105 includes n-type AlGaInP-based material, the contact structure 106 may include Ge. In the case that the second semiconductor layer 105 includes p-type AlGaInP-based material, the contact structure 106 may include Zn. In this embodiment, the contact structure 106 is formed as a metallic film having a thickness greater than 0 Å and less than about 100 Å to ensure that an ohmic contact is formed between the contact structure 106 and the second semiconductor layer 105, and to ensure that a light emitted from the semiconductor epitaxial structure 1 may pass through the contact structure 106 without being absorbed. In some embodiments, the contact structure 106 made of a metal material, which may have a relatively better ductility, may be useful for releasing stress in the light-emitting element 100.

In some embodiments, each of the transparent bonding layer 102 and the mechanical buffer layer 107 is a transparent conductive layer. An electrical conductivity of each of the first and second semiconductor layers 103, 105 may be controlled by adjusting a ratio of a first thickness (T1) of the transparent bonding layer 102 to the second thickness (T2) of the mechanical buffer layer 107 so as to achieve a uniform current distribution in the semiconductor epitaxial structure 1 and an improved brightness of the light-emitting element 100. In this embodiment, the ratio of the first thickness (T1) to the second thickness (T2) ranges from about 2:1 to about 10:1.

### Embodiment 2

FIG. 2 is a schematic cross-sectional view illustrating a second embodiment of the light-emitting element 100 in accordance with the disclosure. Similar numerals from the above-mentioned embodiments have been used where appropriate, with some construction differences being indicated with different numerals.

The second embodiment of the light-emitting element 100 has a structure similar to that of the first embodiment of the light-emitting element 100 except that the contact structure 106 includes a plurality of island-like electrodes 1061 spaced apart from each other and arranged in a two dimensional array. Each of the island-like electrodes 1061 is in ohmic contact with the second semiconductor layer 105. Since the second semiconductor layer 105 has a covering area covered by the contact structure 106 in the second embodiment which is less than a covering area of the second semiconductor layer 105 covered by the contact structure 106 in the first embodiment, absorption of a light emitted from the semiconductor epitaxial structure 1 by the contact structure 106 may be reduced in the second embodiment. It is noted that the mechanical buffer layer 107 which is a transparent conductive layer may extend into a space between two adjacent ones of the island-like electrodes 1061 to be in direct contact with the second semiconductor layer 105. In brief, in the second embodiment of the light-emitting element 100, the mechanical buffer layer 107 may protect the semiconductor epitaxial structure 1, and prevent the semiconductor epitaxial structure 1 from being damaged by an ejector pin used in packaging, thereby improving production yield of the light-emitting element 100. In addition, the island-like electrodes 1061 of the contact structure 106 is able to reduce a ratio of the emitted light being shielded by the contact structure 106.

### Embodiment 3

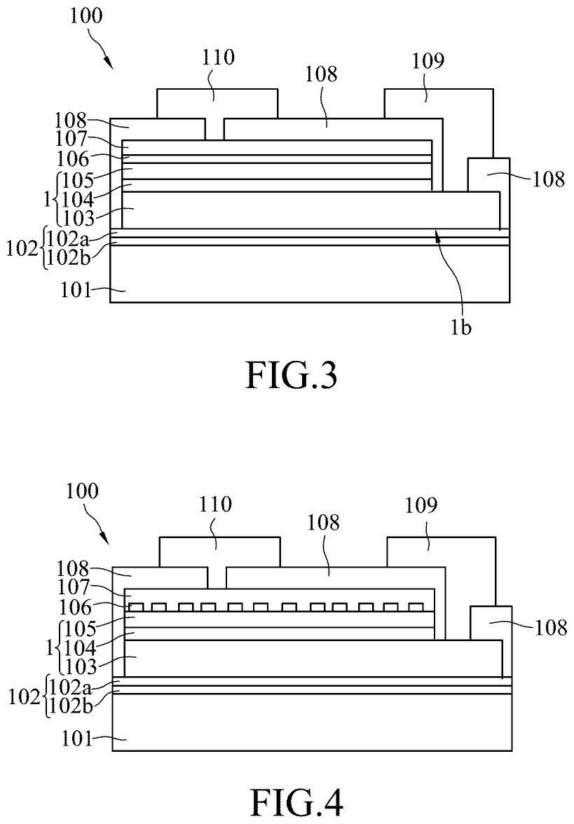

FIG. 3 is a schematic cross-sectional view illustrating a third embodiment of the light-emitting element 100 in accordance with the disclosure. Similar numerals from the above-mentioned embodiments have been used where appropriate, with some construction differences being indicated with different numerals.

The third embodiment of the light-emitting element 100 has a structure similar to that of the first embodiment of the light-emitting element 100 except that the transparent bonding layer 102 is formed as a multi-layered structure, and includes a transparent conductive film 102a which is in contact with the semiconductor epitaxial structure 1, and a transparent insulating film 102b which is in contact with the transparent substrate 101. In some embodiments, the transparent conductive film 102a may include a suitable transparent conductive material (such as the possible materials for the transparent bonding layer 102 described above with reference to FIG. 1), and the transparent insulating film 102b includes aluminum oxide (Al₂O₃), silicon oxide (SiO₂), silicon nitride (SiNₓ), magnesium fluoride (MgF₂), titanium oxide (TiO₂), or combinations thereof. The transparent conductive film 102a may have a thickness ranging from about 0.1 μm to about 1 μm. The transparent insulating film 102b may have a thickness ranging from about 0.1 μm to about 1.4 μm. The transparent conductive film 102a may facilitate current spreading in the first semiconductor layer 103. In addition, since the transparent insulating film 102b has a relatively high bonding strength to the transparent substrate 101, bonding between the semiconductor epitaxial structure 1 and the transparent substrate 101 may be strengthened by introducing the transparent insulating film 102b, thereby further improving a yield of the light-emitting element 100.

### Embodiment 4

FIG. 4 is a schematic cross-sectional view illustrating a fourth embodiment of the light-emitting element 100 in accordance with the disclosure. Similar numerals from the above-mentioned embodiments have been used where appropriate, with some construction differences being indicated with different numerals.

The fourth embodiment of the light-emitting element 100 has a structure similar to that of the second embodiment of the light-emitting element 100 except that the transparent bonding layer 102 has a configuration similar to that of the transparent bonding layer 102 in the third embodiment of the light-emitting element 100. Since the configuration of the contact structure 106 and the transparent bonding layer 102 in this embodiment has been described above with reference to FIGS. 2 and 3, the details thereof are omitted for the sake of brevity.

For the light-emitting element 100 of each of the first to fourth embodiments, the transparent substrate 101 may be thinned down or removed in accordance with some embodiments, thereby obtaining a thin light-emitting element, such as a micron light-emitting element having a thickness less than about 100 μm. In such micron light-emitting element, the mechanical buffer layer 107, which is made from a transparent conductive layer with a predetermined thickness, may improve current spreading in the semiconductor epitaxial structure 1, thereby reducing a voltage applied across the first and second electrodes 109, 110. Furthermore, the mechanical buffer layer 107 may physically support and protect the semiconductor epitaxial structure 1 when the light-emitting element 100 as shown in FIGS. 1 to 4 is flipped upside down.

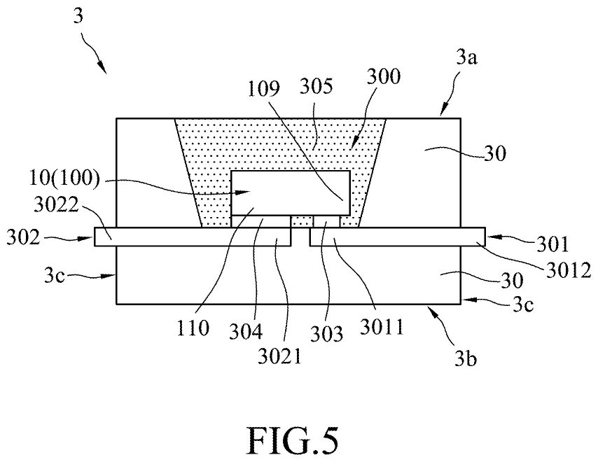

FIG. 5 is a schematic cross-sectional view illustrating an embodiment of a light-emitting diode packaging structure 3 in accordance with the disclosure. Similar numerals from the above-mentioned embodiments have been used where appropriate, with some construction differences being indicated with different numerals. The light-emitting diode packaging structure 3 may be used in various applications, such as backlights and display screens, and may meet brightness requirements of backlight modules.

The light-emitting diode packaging structure 3 includes a mounting substrate 30, a light-emitting assembly 10, a first contact 301, a second contact 302, a first joining part 303, a second joining part 304, and an encapsulant 305.

The mounting substrate 30 is made of an insulating material. For example, the mounting substrate 30 may be a composite substrate for a RGB display screen, or a composite substrate for backlight displays. The mounting substrate 30 has a lower surface 3b, an upper surface 3a opposite to the lower surface 3b, and a peripheral surface 3c connected between the upper and lower surfaces 3a, 3b. The mounting substrate 30 has a receiving space 300 extending inwardly from the upper surface 3a to receive the light-emitting assembly 10.

The first and second contacts 301, 302 are spaced apart from each other, and are partially embedded in the mounting substrate 30. Each of the first and second contacts 301, 302 has a first end 3011, 3021 exposed from the receiving space 300 of the mounting substrate 30, and a second end 3012, 3022 exposed from the peripheral surface 3c of the mounting substrate 30.

The light-emitting assembly 10 may include at least one the light-emitting element 100 of any one of the first to fourth embodiments. In FIG. 5, a single light-emitting element 100 is shown without structural details. The light-emitting element 100 is mounted in the receiving space 300 of the mounting substrate 30. After flipping and rotation of the light-emitting element 100, the first electrode 109 of the light-emitting element 100 is aligned with the first end 3011 of the first contact 301, and is electrically connected to the first contact 301 through the first joining part 303. In addition, the second electrode 110 of the light-emitting element 100 is aligned with the first end 3021 of the second contact 302, and is electrically connected to the second contact 302 through the second joining part 304. Each of the first and second joining parts 303, 304 may be, for example, but not limited to, a solder, such as an eutectic solder or a reflow solder.

A light emitted from the light-emitting diode packaging structure 3 may be a red light (e.g., a light having a wavelength of about 630 nm) or a mixed light (e.g., white light).

The encapsulant 305 is filled in the receiving space 300 for encapsulating and protecting the light-emitting assembly 10, and may be excited to emit a light radiation having a wavelength ranging about 620 nm to about 750 nm.

In some embodiments, the light-emitting diode packaging structure 3 further includes a wavelength conversion material (not shown, for example, but not limited to, phosphor particles) to change a wavelength of the light emitted from the light-emitting assembly 10, such that the light-emitting diode packaging structure 3 may emit a white light. The wavelength conversion material may be dispersed or disposed in the encapsulant 305. In some embodiments, the wavelength conversion material may be excited to emit blue light, green light, or a combination thereof. In some other embodiments, the wavelength conversion material may be excited to emit red light, yellow light, green light, or combinations thereof. The encapsulant 305 may be formed to cover at least one side of the light-emitting assembly 10 by, for example, but not limited to, a dispensing process, a lamination process, or a combination thereof.

The light-emitting diode assembly 3 may be formed by a packaging process, which includes a step of die bonding. During the die bonding step, after the light-emitting element 100 shown in any one of FIGS. 1 to 4 is flipped upside down, the flipped light-emitting element 100 may be lifted up by abutting an ejector pin (not shown) against a central portion of the passivation layer 108 (see FIGS. 1 to 4) at a position between the first and second electrodes 109, 110 and then moving the ejector pin upward. Due to the presence of the mechanical buffer layer 107, the light-emitting element 100, especially the semiconductor epitaxial structure 1 of the light-emitting element 100, may be effectively protected without being damaged when being lifted up by the ejector pin, resulting in an enhanced production yield of the light-emitting element 100.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting element, comprising:
a semiconductor epitaxial structure having a first surface and a second surface opposite to said first surface, and including
a first semiconductor layer defining said second surface,
an active layer disposed on said first semiconductor layer opposite to said second surface to expose a portion of said first semiconductor layer, and
a second semiconductor layer disposed on said active layer opposite to said first semiconductor layer to expose said exposed portion of said first semiconductor layer, said second semiconductor layer having a conductivity type different from that of said first semiconductor layer and defining said first surface opposite to said active layer;
a passivation layer disposed on said first surface of said semiconductor epitaxial structure and said exposed portion of said first semiconductor layer;
a first electrode disposed on said passivation layer and extending through the passivation layer to be electrically connected to said exposed portion of said first semiconductor layer;
a second electrode disposed on said passivation layer and extending through said passivation layer to be electrically connected to said second semiconductor layer; and
a mechanical buffer layer disposed between said passivation layer and said second semiconductor layer.

2. The light-emitting element as claimed in claim 1, further comprising a transparent substrate disposed on said second surface of said semiconductor epitaxial structure.

3. The light-emitting element as claimed in claim 2, further comprising a transparent bonding layer interposed between said transparent substrate and said semiconductor epitaxial structure.

4. The light-emitting element as claimed in claim 3, wherein said transparent bonding layer has a refractive index ranging from 1.2 to 3.

5. The light-emitting element as claimed in claim 3, wherein said transparent bonding layer is formed as a multi-layered structure, and includes a transparent conductive film and a transparent insulating film.

6. The light-emitting element as claimed in claim 5, wherein said transparent insulating film includes aluminum oxide (Al₂O₃), silicon oxide (SiO₂), silicon nitride (SiNₓ), magnesium fluoride (MgF₂), titanium oxide (TiO₂), or combinations thereof.

7. The light-emitting element as claimed in claim 3, wherein said transparent bonding layer is formed as a multi-layered structure or a single-layer structure, and includes a transparent conductive material.

8. The light-emitting element as claimed in claim 1, wherein said mechanical buffer layer is electrically conductive.

9. The light-emitting element as claimed in claim 1, wherein said mechanical buffer layer is transparent or opaque.

10. The light-emitting element as claimed in claim 1, wherein said mechanical buffer layer is a transparent conductive layer.

11. The light-emitting element as claimed in claim 10, wherein said mechanical buffer layer is made of a metal oxide including zinc (Zn), indium (In), tin (Sn), magnesium (Mg), or combinations thereof.

12. The light-emitting element as claimed in claim 11, wherein said mechanical buffer layer is made of zinc oxide (ZnO), indium oxide (In₂O₃), tin oxide (SnO₂), indium tin oxide (ITO), indium zinc oxide (IZO), gallium-doped zinc oxide (GZO), or combinations thereof.

13. The light-emitting element as claimed in claim 1, further comprising a contact structure disposed between said mechanical buffer layer and said second semiconductor layer.

14. The light-emitting element as claimed in claim 13, wherein said contact structure is formed as a metallic film having a thickness less than 100 Å.

15. The light-emitting element as claimed in claim 13, wherein said contact structure includes a plurality of island-like electrodes arranged in a two dimensional array.

16. The light-emitting element as claimed in claim 3, wherein said transparent bonding layer and said mechanical buffer layer have a first thickness and a second thickness, respectively, a ratio of the first thickness to the second thickness ranging from 2:1 to 10:1.

17. The light-emitting element as claimed in claim 1, wherein said mechanical buffer layer has a thickness ranging from 0.1 μm to 1 μm.

18. The light-emitting element as claimed in claim 1, wherein said passivation layer has a thickness ranging from 0.1 μm to 1.4 μm.

19. The light-emitting element as claimed in claim 1, wherein said semiconductor epitaxial structure includes AlGaInP-based material.

20. A light-emitting diode package structure, comprising:
a mounting substrate; and
at least one said light-emitting element as claimed in claim 1 disposed on said mounting substrate.
